(19) United States
(12) Patent Application Publication
(10) Pub. No.: US 2018/0252761 A1
(43) Pub. Date: Sep. 6, 2018

(54) Tool Lifespan Parameter Detector

(71) Applicant: Schlumberger Technology Corporation, Sugar Land, TX (US)

(72) Inventors: Naiwu Yuan, Stafford (GB); Francis Dupouy, Cheltenham (GB); Tamir El-Halawani, Perm (RU); Vikram Rana, Stonehouse, Gloucestershire (GB)

(21) Appl. No.: 15/758,357

(22) PCT Filed: Aug. 31, 2016
(86) PCT No.: PCT/US16/49550

§ 371 Date: Mar. 8, 2018

Related U.S. Application Data
(60) Provisional application No. 62/215,792, filed on Sep. 9, 2015.

(51) Int. Cl. G01R 31/26; G01R 19/165

(52) U.S. Cl. CPC G01R 31/2608; E21B 4/04; G01R 19/165; G01R 31/2621

(57) ABSTRACT

Aspects of the disclosure can relate to systems or devices for detecting a lifespan parameter of a power transistor of an electronic device. In an embodiment, a device can include a differential probe configured to connect to a first terminal and a second terminal of a power transistor. The device can also include a voltage detector that senses a voltage signal from the differential probe and a controller configured to determine a lifespan parameter of the power transistor based on the voltage signal. In another embodiment, the voltage detector and the controller can be included in an electronic device (e.g., a drilling tool or another downhole tool). In another embodiment, the voltage detector can be in the electronic device, where the electronic device includes an external port that provides a differential voltage signal detected by the voltage detector to an external measurement tool (e.g., oscilloscope or the like).

### BACKGROUND

Oil wells are created by drilling a hole into the earth using a drilling rig that rotates a drill string (e.g., drill pipe) having a drill bit attached thereto. The drill bit, aided by the weight of pipes (e.g., drill collars) cuts into rock within the earth. Drilling fluid (e.g., mud) is pumped into the drill pipe and exits at the drill bit. The drilling fluid may be used to cool the bit, lift rock cuttings to the surface, at least partially prevent destabilization of the rock in the wellbore, and/or at least partially overcome the pressure of fluids inside the rock so that the fluids do not enter the wellbore. Other equipment can also be used for evaluating formations, fluids, production, other operations, and so forth.

### SUMMARY

Aspects of the disclosure can relate to systems or devices for detecting a lifespan parameter of a power transistor of an electronic device. In an embodiment, a device can include a differential probe configured to connect to a first terminal and a second terminal of a power transistor. The device can also include a voltage detector that senses a voltage signal from the differential probe, and a controller configured to determine a lifespan parameter of the power transistor based on the voltage signal. In another embodiment, the voltage detector and the controller can be included in an electronic device (e.g., a drilling tool or another downhole tool). In yet another embodiment, the voltage detector can be included in the electronic device, where the electronic device includes an external port that can provide a differential voltage signal detected by the voltage detector to an external measurement tool (e.g., oscilloscope or the like).

This summary is provided to introduce a selection of concepts that are further described below in the detailed description. This summary is not intended to identify key or essential features of the claimed subject matter, nor is it intended to be used as an aid in limiting the scope of the claimed subject matter.

### FIGURES

Embodiments of a tool lifespan parameter detector are described with reference to the following figures. The same numbers are used throughout the figures to reference like features and components.

FIG. 1 illustrates an example system in which various drilling tools can be implemented.

FIG. 2 illustrates an example system in which embodiments of a tool lifespan parameter detector can be implemented.

FIG. 3 illustrates an example system in which embodiments of a tool lifespan parameter detector can be implemented, wherein the tool lifespan parameter detector can be included within a drilling tool.

FIG. 4 illustrates an example system in which embodiments of a tool lifespan parameter detector can be implemented, wherein a portion of the tool lifespan parameter detector can be included within a drilling tool with a testing port for accessing the internal portion of the tool lifespan parameter detector.

### DETAILED DESCRIPTION

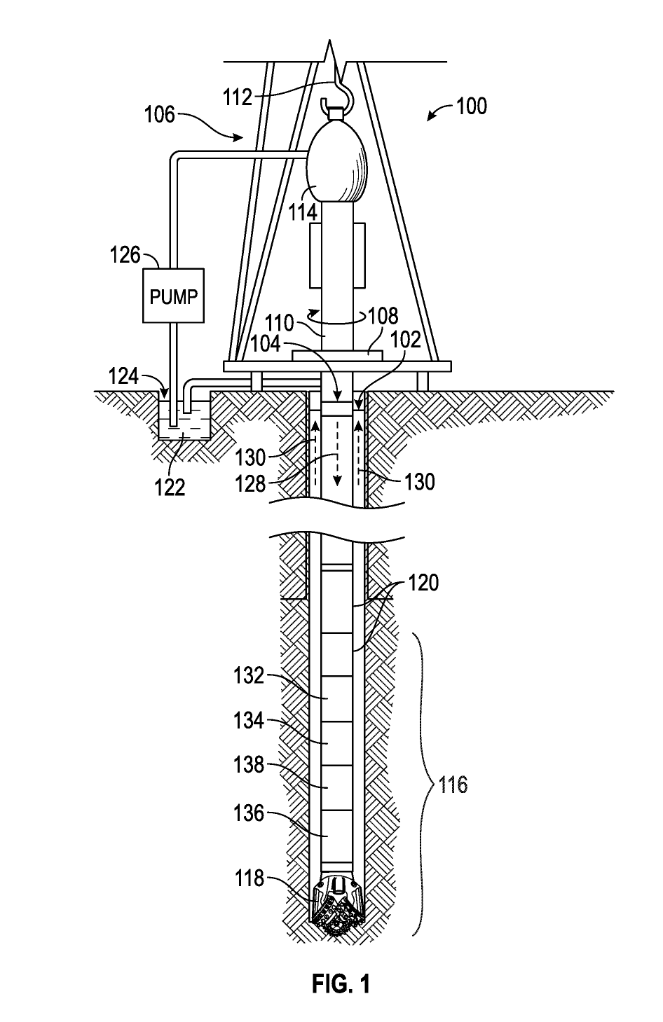

FIG. 1 depicts a wellsite system 100 in accordance with one or more embodiments of the present disclosure. The wellsite can be onshore or offshore. A borehole 102 is formed in subsurface formations by directional drilling. A drill string 104 extends from a drill rig 106 and is suspended within the borehole 102. In some embodiments, the wellsite system 100 implements directional drilling using a rotary steerable system (RSS). For instance, the drill string 104 is rotated from the surface, and down-hole devices move the end of the drill string 104 in a desired direction. The drill rig 106 includes a platform and derrick assembly positioned over the borehole 102. In some embodiments, the drill rig 106 includes a rotary table 108, kelly 110, hook 112, rotary swivel 114, and so forth. For example, the drill string 104 is rotated by the rotary table 108, which engages the kelly 110 at the upper end of the drill string 104. The drill string 104 is suspended from the hook 112 using the rotary swivel 114, which permits rotation of the drill string 104 relative to the hook 112. However, this configuration is provided by way of example and is not meant to limit the present disclosure. For instance, in other embodiments a top drive system is used.

A bottom hole assembly (BHA) 116 is suspended at the end of the drill string 104. The bottom hole assembly 116 includes a drill bit 118 at its lower end. In embodiments of the disclosure, the drill string 104 includes a number of drill pipes 120 that extend the bottom hole assembly 116 and the drill bit 118 into subterranean formations. Drilling fluid (e.g., mud) 122 is stored in a tank and/or a pit 124 formed at the wellsite. The drilling fluid can be water-based, oil-based, and so on. A pump 126 displaces the drilling fluid 122 to an interior passage of the drill string 104 via, for example, a port in the rotary swivel 114, causing the drilling fluid 122 to flow downwardly through the drill string 104 as indicated by directional arrow 128. The drilling fluid 122 exits the drill string 104 via ports (e.g., courses, nozzles) in the drill bit 118, and then circulates upwardly through the annulus region between the outside of the drill string 104 and the wall of the borehole 102, as indicated by directional arrows 130. In this manner, the drilling fluid 122 cools and lubricates the drill bit 118 and carries drill cuttings generated by the drill bit 118 up to the surface (e.g., as the drilling fluid 122 is returned to the pit 124 for recirculation).

In some embodiments, the bottom hole assembly 116 includes down tools, such as a logging-while-drilling (LWD) module 132, a measuring-while-drilling (MWD) module 134, a rotary steerable system 136, a motor, and so forth (e.g., in addition to the drill bit 118). The logging-while-drilling module 132 can be housed in a drill collar and can contain one or a number of logging tools. It should also be noted that more than one LWD module and/or MWD module can be employed (e.g., as represented by another logging-while-drilling module 138). In embodiments of the disclosure, the logging-while drilling modules 132 and/or 138 include capabilities for measuring, processing, and storing information, as well as for communicating with surface equipment, and so forth.

The measuring-while-drilling module 134 can also be housed in a drill collar, and can contain one or more devices for measuring characteristics of the drill string 104 and drill bit 118. The measuring-while-drilling module 134 can also include components for generating electrical power for down-hole tools (e.g., sensors, electrical motors, transmitters, receivers, controllers, energy storage devices, and so forth). For example, the system can include a mud turbine generator (also referred to as a “mud motor”) powered by the flow of the drilling fluid 122. However, this configuration is provided by way of example and is not meant to limit the present disclosure. In other embodiments, other power and/or battery systems can be employed. The measuring-while-drilling module 134 can include one or more of the following measuring devices: a weight-on-bit measuring device, a torque measuring device, a vibration measuring device, a shock measuring device, a stick slip measuring device, a direction measuring device, an inclination measuring device, and so on.

In embodiments of the disclosure, the wellsite system 100 is used with controlled steering or directional drilling. For example, the rotary steerable system 136 is used for directional drilling. As used herein, the term “directional drilling” describes intentional deviation of the wellbore from the path it would naturally take. Thus, directional drilling refers to steering the drill string 104 so that it travels in a desired direction. In some embodiments, directional drilling is used for offshore drilling (e.g., where multiple wells are drilled from a single platform). In other embodiments, directional drilling enables horizontal drilling through a reservoir, which enables a longer length of the wellbore to traverse the reservoir, increasing the production rate from the well. Further, directional drilling may be used in vertical drilling operations. For example, the drill bit 118 may veer off of a planned drilling trajectory because of the unpredictable nature of the formations being penetrated or the varying forces that the drill bit 118 experiences. When such deviation occurs, the wellsite system 100 may be used to guide the drill bit 118 back on course.

Drill assemblies can be used with, for example, a wellsite system (e.g., the wellsite system 100 described with reference to FIG. 1). For instance, a drill assembly can comprise a bottom hole assembly suspended at the end of a drill string (e.g., in the manner of the bottom hole assembly 116 suspended from the drill string 104 depicted in FIG. 1). In some embodiments, a drill assembly is implemented using a drill bit. However, this configuration is provided by way of example and is not meant to limit the present disclosure. In other embodiments, different working implement configurations are used. Further, use of drill assemblies in accordance with the present disclosure is not limited to wellsite systems described herein. Drill assemblies can be used in other various cutting and/or crushing applications, including earth boring applications employing rock scraping, crushing, cutting, and so forth.

A drill assembly includes a body for receiving a flow of drilling fluid. The body comprises one or more crushing and/or cutting implements, such as conical cutters and/or bit cones having spiked teeth (e.g., in the manner of a roller-cone bit). In this configuration, as the drill string is rotated, the bit cones roll along the bottom of the borehole in a circular motion. As they roll, new teeth come in contact with the bottom of the borehole, crushing the rock immediately below and around the bit tooth. As the cone continues to roll, the tooth then lifts off the bottom of the hole and a high-velocity drilling fluid jet strikes the crushed rock chips to remove them from the bottom of the borehole and up the annulus. As this occurs, another tooth makes contact with the bottom of the borehole and creates new rock chips. In this manner, the process of chipping the rock and removing the small rock chips with the fluid jets is continuous. The teeth intermesh on the cones, which helps clean the cones and enables larger teeth to be used. A drill assembly comprising a conical cutter can be implemented as a steel milled-tooth bit, a carbide insert bit, and so forth. However, roller-cone bits are provided by way of example and are not meant to limit the present disclosure. In other embodiments, a drill assembly is arranged differently. For example, the body of the bit comprises one or more polycrystalline diamond compact (PDC) cutters that shear rock with a continuous scraping motion.

In embodiments of the disclosure, the body of a drill assembly can define one or more nozzles that allow the drilling fluid to exit the body (e.g., proximate to the crushing and/or cutting implements). The nozzles allow drilling fluid pumped through, for example, a drill string to exit the body. For example, drilling fluid can be furnished to an interior passage of the drill string by the pump and flow downwardly through the drill string to a drill bit of the bottom hole assembly, which can be implemented using, for example, a drill assembly. Drilling fluid then exits the drill string via nozzles in the drill bit, and circulates upwardly through the annulus region between the outside of the drill string and the wall of the borehole. In this manner, rock cuttings can be lifted to the surface, destabilization of rock in the wellbore can be at least partially prevented, the pressure of fluids inside the rock can be at least partially overcome so that the fluids do not enter the wellbore, and so forth.

Drilling tools (e.g., drill assemblies), other downhole tools (e.g., MWDs, LWDs, various sensors, electrical motors, transmitters, receivers, controllers, energy generators, etc.), as well as electronic devices in fields such as lighting and optical, communication, power generation and transmission, automotive, medical device, consumer electronics, and so forth can include power transistors (e.g., insulated-gate bipolar transistor (IGBT), bipolar junction transistor (BJT), metal oxide semiconductor field-effect transistor (MOSFET), or the like). For example, power transistors can be implemented in power control systems or circuitry of the electronic devices, such as in piecewise affine (PWA) controller circuitry.

Power transistors can be more or less prone to failure in certain electronic devices. For example, IGBTs can be the main power electronics switches of 3-phase bridge inverters in motor drive assemblies of some drilling tools. Yet, in these drilling tools, IGBTs can be one of the most frequently failed parts. As a result, the detection of IGBTs lifespan can aid in predicting and protecting against tool failure. It has been found that certain parameters (e.g., the IGBT Vce (collector-emitter saturation voltage)) provide a measure of the aging status of a power transistor. Certain factors can be considered in order to measure accurately Vce. For example, some signal components (e.g., off-status Vce, transition-status Vce, and/or ripple voltage), sometimes referred to herein as “noise components,” may be excluded to improve accuracy of the Vce measurement. Various measurement techniques are discussed in Fuji Electric Co. Ltd, “Chapter 9: Evaluation and Measurement” (9-3) and is incorporated herein by reference in its entirety.

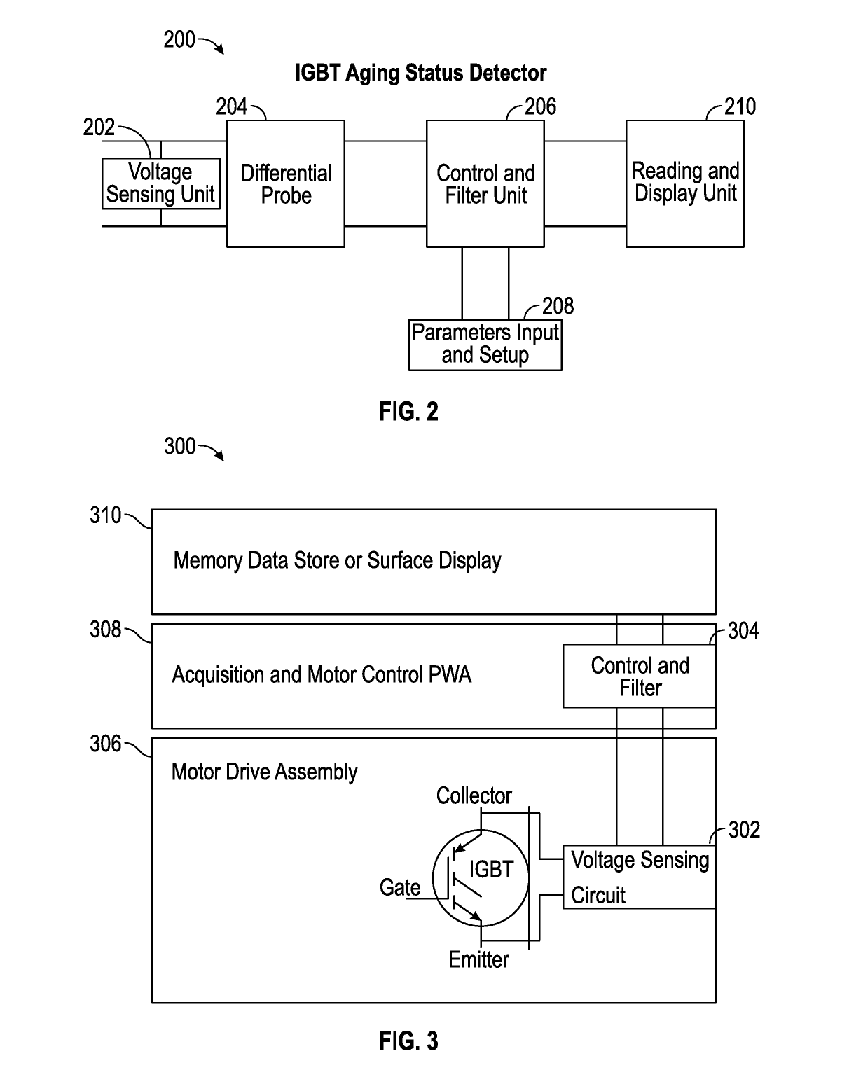

FIGS. 2 through 4 illustrate embodiments of systems or devices for detecting a lifespan parameter of a power transistor of an electronic device. An embodiment is shown in FIG. 2, where a device 200 includes a differential probe 204 configured to connect to a first terminal and a second terminal of a power transistor. For example, the differential probe 204 can include test probes, which probe the collector and emitter pins of an IGBT in a PWA controller circuit. The device 200 also includes a voltage detector 202 that senses a voltage signal from the differential probe. For example, the voltage detector 202 can sense the voltage signal between collector and emitter terminals of the IGBT. In some embodiments, a voltage clipping circuit can be added in series with the voltage detector 202 to improve accuracy of the Vce measurement. A controller 206 (e.g., micro-controller, processor, or the like) that is coupled with the voltage detector 202 and can determined a lifespan parameter (e.g., approximate length of device life remaining, approximate number of remaining uses, level of degradation from original state or condition, or any other indication of remaining device life) of the power transistor based on the voltage signal. In some implementations, such as where the power transistor is a MOSFET, the drain-source voltage (Vds) may be used by probing a drain and source terminals of the MOSFET.

The device 200 can also include a filter that blocks one or more noise components of the voltage signal sensed by the voltage detector 202 in order to improve measurement accuracy. The filter can be implemented by the controller 206, with discrete components, or by another processor, micro-controller, or the like. In some embodiments, the noise components include one or more of: off-status voltage between the first terminal and the second terminal; transition-status voltage between the first terminal and the second terminal; or ripple voltage from the first terminal or the second terminal. The filter can implement a high-pass filter, band-pass filter, low-pass filter, and/or signal filtration or isolation techniques discussed in Fuji Electric Co. Ltd, “Chapter 9: Evaluation and Measurement” (9-3), or the like.

In some embodiments, the controller 206 is communicatively coupled to a user input device 208 (e.g., one or more of: a keyboard, mouse, buttons, switches, dials, a touch pad, a touch panel, or the like) that can be used to enter reference parameters associated with the power transistor, such as nominal operating parameters, tolerance ranges, device specifications, and so forth. According to these reference parameters and the detected voltage signal, the controller 206 can determine one or more lifespan parameters of the power transistor, and as such, the controller can also determine one or more lifespan parameters of an electronic device or tool including the power transistor. In this regard, the tool lifespan may be equal to the lifespan of the power transistor or can be determined by factoring in the determined (e.g., approximated) lifespan of the power transistor. For example, the tool lifespan may be determined by multiplying the lifespan of the power transistor by a factor to account for tool breakdown that can occur when the power transistor operates outside of a certain tolerance. In some implementations, the lifespan of the tool can be determined based on two or more power transistors, where the tool is prone to failure when at least one of the two or more power transistors fails. For example, the tool lifespan can be based on time where the probability of at least one of the two or more power transistors failing is above a threshold probability value.

The device 200 can also include an indicator 210 (e.g., LCD or LED display) coupled to the controller 206. The indicator 210 can provide a visual indication associated with the determined lifespan parameter of the power transistor. In some embodiments, audible indicators (e.g., alarms) can also be used. In some embodiments, the indicator 210 provides a measure, numerical representation, or graphical plot of the voltage signal, which can be filtered to exclude noise components, as discussed above. In some embodiments, the indicator 210 can provide some reference information about the aging status or lifespan of the power transistor, an estimate of the remaining useful life of the power transistor, or an assessment of a risk of failure associated with continued use of the power transistor.

The device 200 can be a standalone device that is used to detect or determine lifespan parameters for electronic devices on an ad-hoc basis. For example, the device 200 can be used to test drilling tools and other downhole equipment at the surface by probing one or more power transistors included in power distribution and/or control circuitry (e.g., PWA controller circuitry) of the tool being tested. Additional implementations of tool lifespan parameter testing systems are discussed herein, where, for example, various detection components, such as those of device 200, can be implemented within an electronic device or tool. Embodiments are discussed herein where detection components are implemented within a drilling tool; however, it is to be understood that the detection components can be implemented within any electronic device that includes a power transistor.

Referring to FIG. 3, an embodiment is shown where a drilling tool 300 includes a voltage detector 302 (e.g., like detector 202) and a controller 304 (e.g., like controller 206) integrated within its architecture. For example, the voltage detector 302 can be coupled to first and second terminals (e.g., collector and emitter terminals) of a power transistor in a drive assembly 306 of the drilling tool 300. In some embodiments, a voltage clipping circuit is included in series with the voltage detector 302. The controller 304 can comprise a controller coupled or integrated with, or implemented by, the power and/or motor controller 308 (e.g., an acquisition and motor control PWA controller) of the drilling tool 300. For example, a digital signal processor (DSP) on the power and/or motor controller 308 can receive and process (e.g., filter) a differential voltage signal sensed by the voltage detector 302. Because the driving signals of the power transistor (e.g., pulse-width modulation (PWM) signals) may be generated by the DSP, the DSP can be configured to collect the on-status voltage signal at a time point when the power transistor is in stable switching on stage. As a result, some noise parameters (e.g., transition-stage Vce, switching off-stage Vce) can be easily filtered off.

Like other D-point values, the Vce value can be displayed in a tool monitoring apparatus or saved in log files (e.g., memory storage or display device 310). In embodiments, the drilling tool 300 can include a communication module (e.g., modem or other transmitter/receiver) that transmits a lifespan parameter (e.g., voltage signal value, etc.) to a surface display, which may be coupled to a surface computer or remotely located server that monitors the tool. In some embodiments, the drilling tool 300 includes its own local memory (e.g., flash or solid-state memory) for storing the measured and/or determined parameters in a tool log.

Auxiliary parameters can also be used to determine Vce or compare with the measured Vce to determine a lifespan parameter of the power transistor. For example, Vce value can be relative to the IGBT junction temperature and Ice (collector-emitter current) of the IGBT. In existing D-points, the HSTEMP (temperature of IGBT block) could be a reference for IGBT junction temperature, and the phase current could be a reference for Ice.

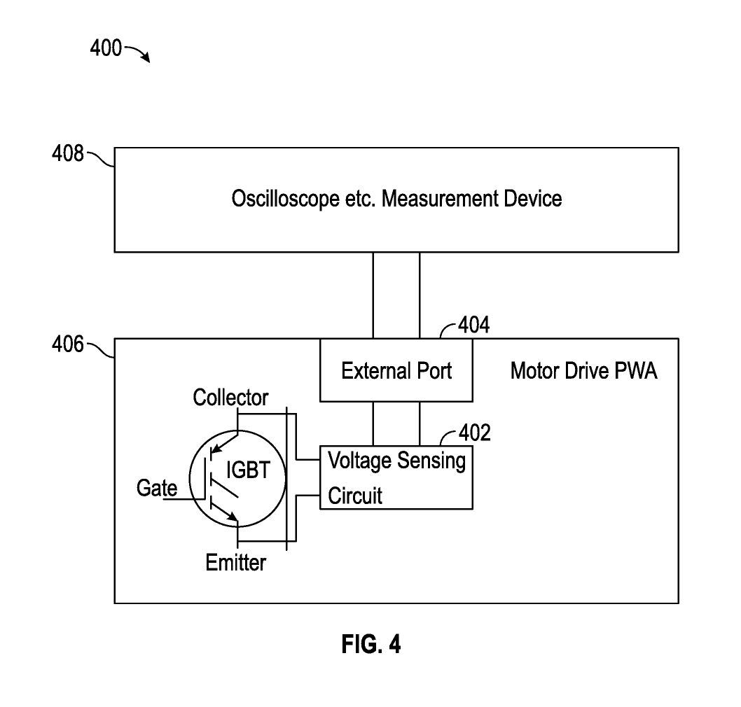

Referring now to FIG. 4, another embodiment is shown where a drilling tool 400 includes a voltage detector 402 (e.g., like voltage detector 202) implemented within its motor device assembly 406 (e.g., as part of the motor drive PWA circuitry). The voltage detector 402 can be coupled with the first and second terminals (e.g., collector and emitter terminals) of a power transistor within the drilling tool 400. In some embodiments, a voltage clipping circuit is included in series with the voltage detector 402. The voltage detector 402 is also coupled with an external port 404 (e.g., two or more external pins or connectors) that can be accessed (e.g., probed or connected to) by an external measurement tool 408 (e.g., oscilloscope or the like). In this manner the external measurement tool 408 is enabled to receive the differential voltage signal between the first and second terminals of the power transistor via the external port 404. In some implementations, the external port 404 can be an existing port of a motor drive PWA. In other embodiments, the external port 404 can be a separate dedicated port for testing the voltage signal (e.g., Vce, Vds, or the like) between the first and second terminals of the power transistor.

Although only a few example embodiments have been described in detail above, those skilled in the art will readily appreciate that many modifications are possible in the example embodiments without materially departing from the scope of this disclosure. Features shown in individual embodiments referred to above may be used together in combinations other than those which have been shown and described specifically. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112, paragraph 6 for any limitations of any of the claims herein, except for those in which the claim expressly uses the words ‘means for’ together with an associated function.

What is claimed is:

1. A device for detecting a lifespan parameter of a power transistor of an electronic device, comprising:
a differential probe configured to connect to a first terminal and a second terminal of a power transistor;
a voltage detector that senses a voltage signal from the differential probe; and
a controller configured to determine a lifespan parameter of the power transistor based on the voltage signal.

2. The device as recited in claim 1, further comprising:
a filter that blocks one or more noise components of the voltage signal.

3. The device as recited in claim 2, wherein the one or more noise components comprise one or more of: off-status voltage between the first terminal and the second terminal; transition-status voltage between the first terminal and the second terminal; or ripple voltage from the first terminal or the second terminal.

4. The device as recited in claim 1, wherein the power transistor comprises an insulated-gate bipolar transistor.

5. The device as recited in claim 1, wherein the power transistor comprises a bipolar junction transistor or a metal oxide semiconductor field-effect transistor.

6. The device as recited in claim 1, further comprising
an indicator coupled to the controller, the indicator being configured to provide a visual indication associated with the determined lifespan parameter of the power transistor.

7. A drilling tool, comprising:
a motor drive assembly including a power transistor;
a voltage detector coupled to a first terminal and a second terminal of the power transistor; and
a controller configured to determine a lifespan parameter of the power transistor of the motor drive assembly based on a differential voltage signal detected by the voltage detector.

8. The drilling tool as recited in claim 7, further comprising:
a filter that blocks one or more noise components of the differential voltage signal.

9. The drilling tool as recited in claim 7, wherein the power transistor comprises an insulated-gate bipolar transistor.

10. The drilling tool as recited in claim 7, wherein the power transistor comprises a bipolar junction transistor or a metal oxide semiconductor field-effect transistor.

11. The drilling tool as recited in claim 7, further comprising:
a communication module coupled to the controller, the communication module being configured to transmit the determined lifespan parameter of the power transistor to a surface display.

12. The drilling tool as recited in claim 7, further comprising:
a memory device configured to store the determined lifespan parameter of the power transistor in a tool log.
